(19) United States
(12) Patent Application Publication
(10) Pub. No.: US 2016/0266498 A1
(43) Pub. Date: Sep. 15, 2016

(54) LITHOGRAPHY APPARATUS, PATTERNING DEVICE, AND LITHOGRAPHIC METHOD

(71) Applicant: ASML NETHERLANDS B.V., Veldhoven (NL)

(72) Inventors: Pieter Willem Herman DE JAGER, Middelbeers (NL); Robert Albertus Johannes VAN DER WERF, Eindhoven (NL)

(73) Assignee: ASML Netherlands B.V., Veldhoven (NL)

(21) Appl. No.: 15/030,569

(22) PCT Filed: Oct. 10, 2014
(86) PCT No.: PCT/EP2014/071786

§ 371 Date: Apr. 19, 2016

Related U.S. Application Data
(60) Provisional application No. 61/895,865, filed on Oct. 25, 2013.

(51) Int. Cl. G03F 7/20

(52) U.S. Cl. CPC G03F 7/7015

(57) ABSTRACT

An exposure apparatus including: a substrate holder constructed to hold a substrate; a modulator, including a plurality of VECSELs or VCSELs to emit electromagnetic radiation, configured to expose an exposure area of a target portion to a plurality of beams of the radiation modulated according to a desired pattern, and a projection system configured to project the modulated beams onto the target portion and having an array of optical elements to receive the plurality of beams, the projection system configured to move the array of optical elements with respect to the plurality of VECSELs or VCSELs during exposure of the exposure area, wherein the movement involves rotation and/or the movement causes the beams to displace.

### CROSS-REFERENCE TO RELATED APPLICATIONS

This application claims the benefit of U.S. provisional application 61/895,865, which was filed on Oct. 25, 2013 and which is incorporated herein in its entirety by reference.

### FIELD

The present invention relates to a lithographic or exposure apparatus, a patterning device, and a lithographic or manufacturing method.

### BACKGROUND

A lithographic or exposure apparatus is a machine that applies a desired pattern onto a substrate or part of a substrate. A lithographic or exposure apparatus may be used, for example, in the manufacture of integrated circuits (ICs), flat panel displays and other devices or structures having fine features. In a conventional lithographic or exposure apparatus, a patterning device, which may be referred to as a mask or a reticle, may be used to generate a circuit pattern corresponding to an individual layer of the IC, flat panel display, or other device). This pattern may transferred on (part of) the substrate (e.g. silicon wafer or a glass plate), e.g. via imaging onto a layer of radiation-sensitive material (resist) provided on the substrate.

Instead of a circuit pattern, the patterning device may be used to generate other patterns, for example a color filter pattern, or a matrix of dots. Instead of a conventional mask, the patterning device may comprise a patterning array that comprises an array of individually controllable elements that generate the circuit or other applicable pattern. An advantage of such a “maskless” system compared to a conventional mask-based system is that the pattern can be provided and/or changed more quickly and for less cost.

Thus, a maskless system includes a programmable patterning device (e.g., a spatial light modulator, a contrast device, etc.). The programmable patterning device is programmed (e.g., electronically or optically) to form the desired patterned beam using the array of individually controllable elements. Types of programmable patterning devices include micro-mirror arrays, liquid crystal display (LCD) arrays, grating light valve arrays, arrays of self-emissive contrast devices, a shutter element/matrix and the like. A programmable patterning device could also be formed from an electro-optical deflector, configured for example to move spots of radiation projected onto the substrate or to intermittently direct a radiation beam away from the substrate, for example to a radiation beam absorber. In either such arrangement, the radiation beam may be continuous.

### SUMMARY

According to an embodiment, there is provided an exposure apparatus comprising: a substrate holder constructed to hold a substrate; a modulator, comprising a plurality of radiation sources to emit electromagnetic radiation, configured to expose a target portion to a plurality of beams of the radiation modulated according to a desired pattern; a projection system configured to project the modulated beams onto the target portion and comprising an array of optical elements to receive the plurality of beams; and an actuator configured to move the array of optical elements with respect to the plurality of radiation sources during exposure of the target portion, wherein a two-dimensional array of the plurality of the beams is imaged with a single optical element of the plurality of optical elements.

According to an embodiment, there is provided an exposure apparatus comprising: a programmable patterning device having a plurality of radiation sources to provide a plurality of beams; and a movable frame having optical elements to receive the radiation beams from the plurality of radiation sources and project the beams toward a target portion and a substrate, the optical elements being refractive optical elements, wherein a two-dimensional array of the plurality of the beams is imaged with a single optical element of the plurality of optical elements.

According to an embodiment, there is provided a programmable patterning device, comprising: a plurality of radiation sources to provide a plurality of beams modulated according to a desired pattern; an array of optical elements to receive the plurality of beams; and an actuator configured to move the array of optical elements with respect to the beams during provision of the plurality of beams, wherein a two-dimensional array of the plurality of the beams is imaged with a single optical element of the plurality of optical elements.

According to an embodiment, there is provided a device manufacturing method comprising: providing a plurality of beams of radiation modulated according to a desired pattern using a plurality of radiation sources that provide the radiation; projecting the plurality of beams onto a target portion using an array of optical elements that receive the plurality of beams; and moving the array of optical elements with respect to the beams during the projecting, wherein a two-dimensional array of the plurality of the beams is imaged with a single optical element of the plurality of optical elements.

According to an embodiment, there is provided a device manufacturing method comprising: modulating a plurality of radiation sources to provide a plurality of beams modulated according to a pattern; moving a frame having optical elements to receive the radiation beams from the plurality of radiation sources; and projecting the beams, from the optical elements, toward a target portion and a substrate, the optical elements being refractive optical elements, wherein a two-dimensional array of the plurality of the beams is imaged with a single optical element of the plurality of optical elements.

In an embodiment, the plurality of radiation sources comprises a plurality of VECSELs or VCSELs.

According to an embodiment, there is provided an exposure apparatus comprising: a substrate holder constructed to hold a substrate; a VECSEL or VCSEL to provide a beam of radiation; a donor structure, in use, located in the optical path from the VECSEL or VCSEL to the substrate, the donor structure configured to support a donor material layer transferable from the donor structure onto the substrate and onto which the beam impinges, the beam not being frequency multiplied; and a projection system configured to project the beam onto the donor material layer.

According to an embodiment, there is provided a device manufacturing method comprising: providing a beam of radiation using a VECSEL or VCSEL; projecting the beam onto a target portion of a donor layer of a material, the donor layer supported by a donor structure located in the optical path from the VECSEL or VCSEL to a substrate, the beam not being frequency multiplied; and transferring the material from the donor layer on which the beam impinges from the donor structure onto the substrate.

According to an embodiment, there is provided a device manufacturing method comprising: providing a beam of radiation using a VECSEL or VCSEL; and projecting the beam onto a target portion of a layer comprising particles of a material, the layer on a substrate and the beam sintering the particles to form a part of a pattern on the substrate.

According to an embodiment, there is provided an exposure apparatus comprising: a substrate holder constructed to hold a substrate; a modulator, comprising a plurality of radiation sources to emit electromagnetic radiation, configured to expose a target portion to a plurality of beams of the radiation modulated according to a desired pattern, the radiation sources arranged at a pitch of less or equal to 2000 microns; a projection system configured to project the modulated beams onto the target portion and comprising an array of optical elements to receive the plurality of beams; and an actuator configured to move the array of optical elements with respect to the plurality of radiation sources during exposure of the target portion.

According to an embodiment, there is provided an exposure apparatus comprising: a programmable patterning device having a plurality of radiation sources to provide a plurality of beams, the radiation sources arranged at a pitch of less or equal to 2000 microns; and a movable frame having an optical element to receive the radiation beams from the plurality of radiation sources and project the beams toward a target portion and a substrate.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a part of a lithographic or exposure apparatus according to an embodiment of the invention;

FIG. 2 depicts a top view of a part of the apparatus of FIG. 1 according to an embodiment of the invention;

FIG. 3 depicts a highly schematic, perspective view of a part of a lithographic or exposure apparatus according to an embodiment of the invention;

FIG. 4 depicts a schematic top view of projections by the apparatus according to FIG. 3 onto a target portion according to an embodiment of the invention;

FIG. 5 depicts in cross-section, a part of an embodiment of the invention;

FIG. 6 depicts a highly schematic, perspective view of a part of a lithographic or exposure apparatus according to an embodiment of the invention;

FIG. 7 depicts a radiation source comprising an array of VECSELs;

FIG. 8 depicts a combination of a radiation source comprising VECSELs and a frequency multiplying device;

FIG. 9 depicts an example VECSEL configuration;

FIG. 10 depicts a schematic top view of projections by the apparatus according to FIG. 6, 7 or 8 onto a target portion according to an embodiment of the invention; and

FIG. 11 depicts in cross-section, a part of an embodiment of the invention.

### DETAILED DESCRIPTION

An embodiment of the present invention relates to an apparatus that may include a programmable patterning device that may, for example, be comprised of an array or arrays of self-emissive contrast devices. Further information regarding such an apparatus may be found in PCT patent application publication no. WO 2010/032224 A2, U.S. patent application publication no. US 2011-0188016, U.S. patent application no. U.S. 61/473,636, U.S. patent application No. 61/524,190, U.S. patent application No. 61/654,575, and U.S. patent application No. 61/668,924, which are hereby incorporated by reference in their entireties. An embodiment of the present invention, however, may be used with any form of programmable patterning device including, for example, those discussed above.

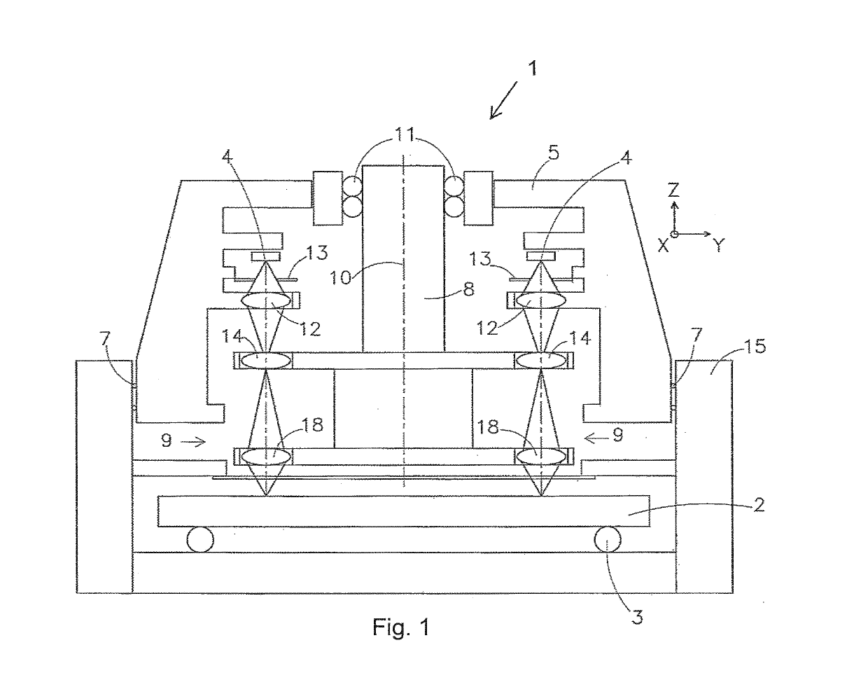

FIG. 1 schematically depicts a schematic cross-sectional side view of a part of a lithographic or exposure apparatus. In this embodiment, the apparatus has individually controllable elements substantially stationary in the X-Y plane as discussed further below although it need not be the case. The apparatus 1 comprises a substrate table 2 to hold a substrate, and a positioning device 3 to move the substrate table 2 in up to 6 degrees of freedom. The substrate may be a resist-coated substrate. In an embodiment, the substrate is a wafer. In an embodiment, the substrate is a polygonal (e.g. rectangular) substrate. In an embodiment, the substrate is a glass plate. In an embodiment, the substrate is a plastic substrate. In an embodiment, the substrate is a foil. In an embodiment, the apparatus is suitable for roll-to-roll manufacturing.

The apparatus 1 further comprises a plurality of individually controllable self-emissive contrast devices 4 configured to emit a plurality of beams. In an embodiment, the self-emissive contrast device 4 is a radiation emitting diode, such as a light emitting diode (LED), an organic LED (OLED), a polymer LED (PLED), a laser diode (e.g., a solid state laser diode), a micro LED (generally, LEDs with a diameter of less than 100 micron; see, e.g., U.S. Pat. No. 7,598,149, WO-2013-093464, WO-2013-0117944; all three hereby incorporated in their entirety by reference), a vertical-external-cavity surface-emitting laser (VECSEL) or a vertical-cavity surface-emitting laser (VCSEL). In an embodiment, each of the individually controllable elements 4 is a blue-violet laser diode (e.g., Sanyo model no. DL-3146-151). Such diodes may be supplied by companies such as Sanyo, Nichia, Osram, and Nitride. In an embodiment, the self-emissive contrast device 4 emits UV radiation, e.g., having a wavelength in the range of 124 nm to 1000 nm such as about 193 nm, about 365 nm, about 405 nm or about 800 nm. In an embodiment, the self-emissive contrast device 4 can provide an output power selected from the range of 0.5-200 mW. In an embodiment, the size of self-emissive contrast device 4 (naked die) is selected from the range of 100-800 micrometers. In an embodiment, the self-emissive contrast device 4 has an emission area selected from the range of 0.5-200 micrometers². In an embodiment, the self-emissive contrast device 4 has a divergence angle selected from the range of 5-44 degrees. In an embodiment, the self-emissive contrast device 4 have a configuration (e.g., emission area, divergence angle, output power, etc.) to provide a total brightness more than or equal to about 6.4×10⁸ W/(m².sr).

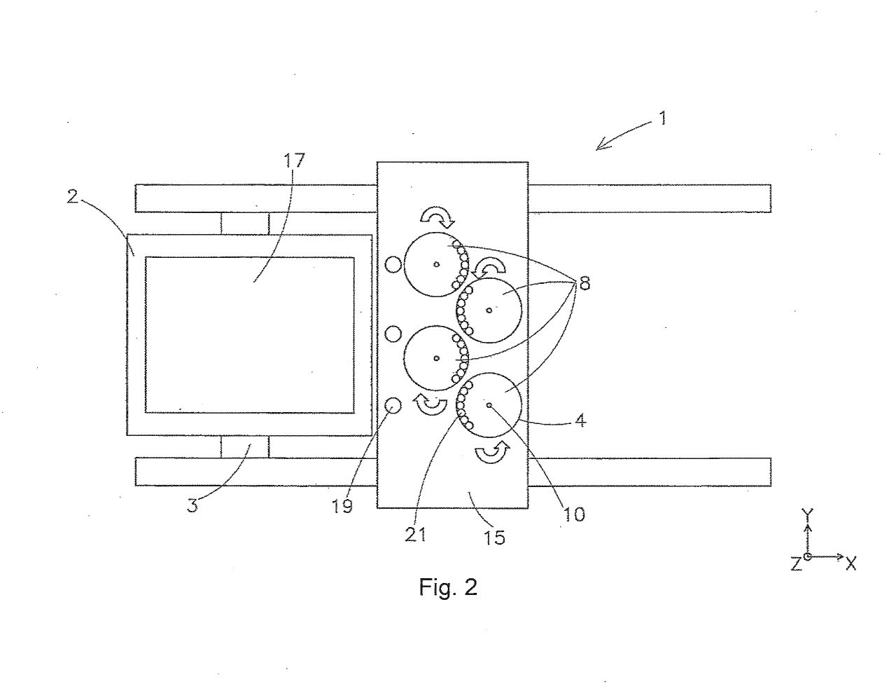

The self-emissive contrast devices 4 are arranged on a frame 5 and may extend along the Y-direction and/or the X direction. While one frame 5 is shown, the apparatus may have a plurality of frames 5 as shown in FIG. 2. Further arranged on the frame 5 is lens 12. Frame 5 and thus self-emissive contrast device 4 and lens 12 are substantially stationary in the X-Y plane. Frame 5, self-emissive contrast device 4 and lens 12 may be moved in the Z-direction by actuator 7. Alternatively or additionally, lens 12 may be moved in the Z-direction by an actuator related to this particular lens. Optionally, each lens 12 may be provided with an actuator.

The self-emissive contrast device 4 may be configured to emit a beam and the projection system 12, 14 and 18 may be configured to project the beam onto a target portion of, e.g., the substrate in, e.g., a resist-based exposure process. The self-emissive contrast device 4 and the projection system form an optical column. As shown in FIG. 2, the apparatus 1 may comprises a plurality of optical columns (four are shown in FIG. 2 but more or less optical columns may be provided). The apparatus 1 may comprise an actuator (e.g. motor 11) to move the optical column or a part thereof with respect to the substrate. Frame 8 with arranged thereon field lens 14 and imaging lens 18 may be rotatable with the actuator. A combination of field lens 14 and imaging lens 18 forms movable optics 9. In use, the frame 8 rotates about its own axis 10, for example, in the directions shown by the arrows in FIG. 2. The frame 8 is rotated about the axis 10 using an actuator e.g. motor 11. Further, the frame 8 may be moved in a Z direction by motor 7 so that the movable optics 9 may be displaced relative to the substrate table 2.

An aperture structure 13 having an aperture therein may be located above lens 12 between the lens 12 and the self-emissive contrast device 4. The aperture structure 13 can limit diffraction effects of the lens 12, the associated self-emissive contrast device 4, and/or of an adjacent lens 12/self-emissive contrast device 4.

The depicted apparatus may be used by rotating the frame 8 and simultaneously moving the substrate on the substrate table 2 underneath the optical column. The self-emissive contrast device 4 can emit a beam through the lenses 12, 14, and 18 when the lenses are substantially aligned with each other. By moving the lenses 14 and 18, the image of the beam is scanned over and onto a target portion of, e.g., the substrate. By simultaneously moving, e.g., the substrate on the substrate table 2 underneath the optical column, the target portion which is subjected to an image of the self-emissive contrast device 4 is also moving. By switching the self-emissive contrast device 4 “on” and “off” (e.g., having no output or output below a threshold when it is “off” and having an output above a threshold when it is “on”) at high speed under control of a controller, controlling the rotation of the optical column or part thereof, controlling the intensity of the self-emissive contrast device 4, and controlling the speed of, e.g., the substrate, a desired pattern can be imaged in, e.g., the resist layer on the substrate.

FIG. 2 depicts a schematic top view of the apparatus of FIG. 1 having self-emissive contrast devices 4. Like the apparatus 1 shown in FIG. 1, the apparatus 1 comprises a substrate table 2 to hold a substrate 17, a positioning device 3 to move the substrate table 2 in up to 6 degrees of freedom, an alignment/level sensor 19 to determine alignment between the self-emissive contrast device 4 and, e.g., the substrate 17, and to determine whether, e.g., the substrate 17 is at level with respect to the projection of the self-emissive contrast device 4. As depicted the substrate 17 has a rectangular shape, however also or alternatively round substrates may be processed.

The self-emissive contrast device 4 is arranged on a frame 15. The self-emissive contrast device 4 may be a radiation emitting diode, e.g., a laser diode, for instance a blue-violet laser diode. As shown in FIG. 2, the self-emissive contrast devices 4 may be arranged into an array 21 extending in the X-Y plane.

The array 21 may be an elongate line. In an embodiment, the array 21 may be a single dimensional array of self-emissive contrast devices 4. In an embodiment, the array 21 may be a two dimensional array of self-emissive contrast device 4.

A rotating frame 8 may be provided which may be rotating in a direction depicted by the arrow. The rotating frame may be provided with lenses 14, 18 (shown in FIG. 1) to provide an image of each of the self-emissive contrast devices 4. The apparatus may be provided with an actuator to rotate the optical column comprising the frame 8 and the lenses 14, 18 with respect to the substrate.

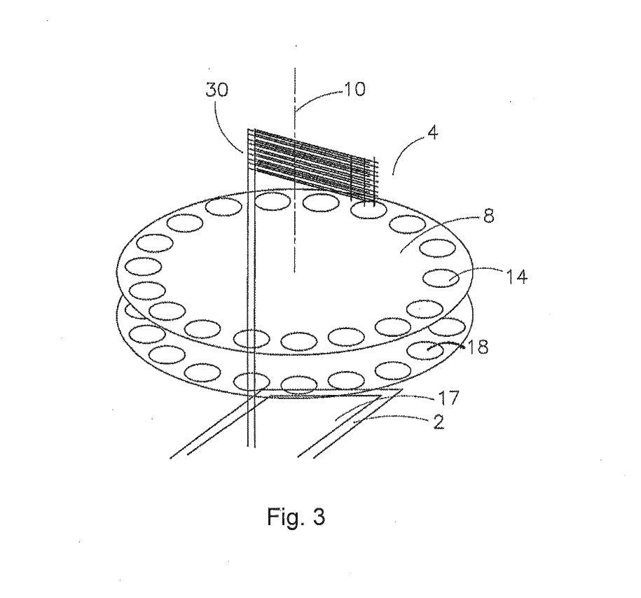

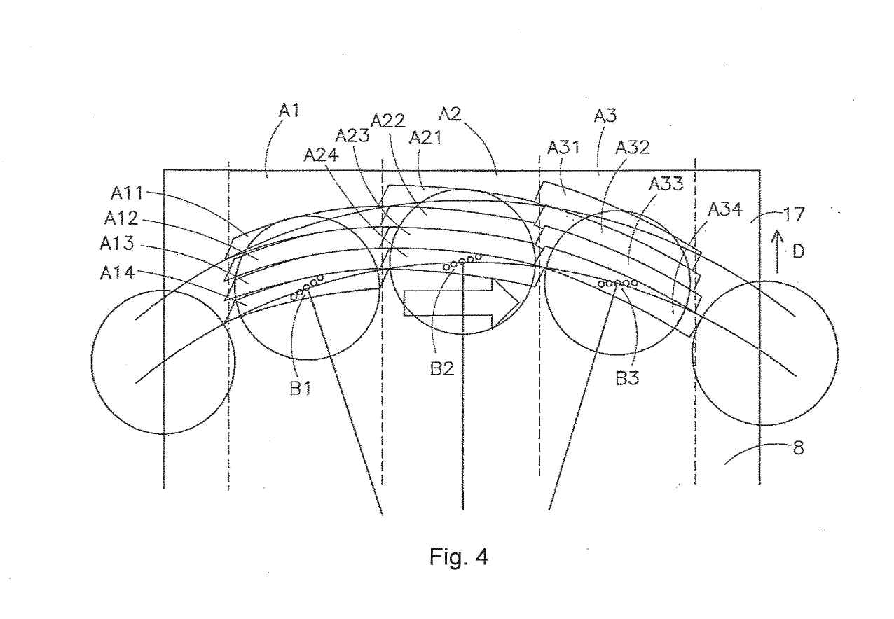

FIG. 3 depicts a highly schematic, perspective view of the rotating frame 8 provided with lenses 14, 18 at its perimeter. A plurality of beams, in this example 10 beams, are incident onto one of the lenses and projected onto a target portion of, e.g., the substrate 17 held by the substrate table 2. In an embodiment, the beams are arranged in a straight line. The rotatable frame is rotatable about axis 10 by means of an actuator (not shown). As a result of the rotation of the rotatable frame 8, the beams will be incident on successive lenses 14, 18 (field lens 14 and imaging lens 18) and will, incident on each successive lens, be deflected thereby so as to travel along a part of the target portion, as will be explained in more detail with reference to FIG. 4. In an embodiment, each beam is generated by a respective source, i.e. a self-emissive contrast device, e.g. a laser diode (not shown in FIG. 3). In the arrangement depicted in FIG. 3, the beams are deflected and brought together by a segmented mirror 30 in order to reduce a distance between the beams, to thereby enable a larger number of beams to be projected through the same lens and to achieve resolution requirements to be discussed below.

As the rotatable frame rotates, the beams are incident on successive lenses and, each time a lens is irradiated by the beams, the places where the beam is incident on a surface of the lens, moves. Since the beams are projected differently (with e.g. a different deflection) depending on the place of incidence of the beams on the lens, the beams (when reaching the target portion) will make a scanning movement with each passage of a following lens. This principle is further explained with reference to FIG. 4.

FIG. 4 depicts a highly schematic top view of projections by a part of the rotatable frame 8 of an optical column of FIG. 3 onto a target portion. A first set of beams is denoted by B1, a second set of beams is denoted by B2 and a third set of beams is denoted by B3. Each set of beams is projected through a respective lens set 14, 18 of the rotatable frame 8. As the rotatable frame 8 rotates, the beams B1 are projected onto a target portion of, e.g., the substrate 17 in a scanning movement, thereby scanning area A14. Similarly, beams B2 scan area A24 and beams B3 scan area A34. At the same time of the rotation of the rotatable frame 8 by a corresponding actuator, the substrate 17 and substrate table are moved in the direction D (which may be along the X axis as depicted in FIG. 2), thereby being substantially perpendicular to the scanning direction of the beams in the area's A14, A24, A34. As a result of the movement in direction D by a second actuator (e.g. a movement of the substrate table by a corresponding substrate table motor), successive scans of the beams when being projected by successive lenses of the rotatable frame 8, are projected so as to substantially abut each other, resulting in substantially abutting areas A11, A12, A13, A14 (areas A11, A12, A13 being previously scanned and A14 being currently scanned as shown in FIG. 4) for each successive scan of beams Bl, areas A21, A22, A23 and A24 (areas A21, A22, A23 being previously scanned and A24 being currently scanned as shown in FIG. 4) for beams B2 and areas A31, A32, A33 and A34 (areas A31, A32, A33 being previously scanned and A34 being currently scanned as shown in FIG. 4) for beams B3. Thereby, the areas A1, A2 and A3 of, e.g., the substrate surface may be covered with a movement of the substrate in the direction D while rotating the rotatable frame 8.

Thus, with this system layout of individually addressable elements (e.g., laser diodes) and moving lenses, a substrate is patterned while the lenses move and the substrate scans. Modulation of the individually addressable elements (e.g., laser diodes) output generates the pattern on the substrate. As can be seen in FIG. 4, the projection scheme enables movement stitching. That is, when using a single movable lens, each area A11, A12, etc. is exposed during a single movement of the lens (e.g., rotation of the frame 8). Further, the projection scheme enables individually addressable element stitching. That is, for each area A11, multiple individually addressable element (e.g., laser diode) beams are imaged on the target portion. Further, the projection scheme enables illumination stitching. That is, in the slit direction, each area A11, A12, etc. is exposed with different individually addressable element (e.g., laser diode) beams and with the same lenses. Further, the projection scheme enables lens stitching. That is, in the scan direction, each area is exposed with the same individually addressable element (e.g., laser diode) beams and with different lenses. Further, the projection scheme enables optical column stitching. That is, the width of the target portion (e.g., substrate) is exposed by multiple adjacent optical columns.

The projecting of multiple beams through a same lens allows processing of a whole substrate in a shorter timeframe (at a same rotating speed of the rotatable frame 8), since for each passing of a lens, a plurality of beams scan the target portion of, e.g., a substrate with each lens, thereby allowing increased displacement in the direction D for successive scans. Viewed differently, for a given processing time, the rotating speed of the rotatable frame may be reduced when multiple beams are projected toward the substrate via a same lens, thereby possibly reducing effects such as deformation of the rotatable frame, wear, vibrations, turbulence, etc. due to high rotating speed. In an embodiment, the beams are arranged at an angle to the tangent of the rotation of the lenses 14, 18 as shown in FIG. 4. In an embodiment, the beams are arranged such that each beam overlaps or abuts a scanning path of an adjacent beam.

A further effect of the aspect that multiple beams are projected at a time by the same lens, may be found in relaxation of tolerances. Due to tolerances of the lenses (positioning, optical projection, etc), positions of successive areas A11, A12, A13, A14 (and/or of areas A21, A22, A23 and A24 and/or of areas A31, A32, A33 and A34) may show some degree of positioning inaccuracy in respect of each other. Therefore, some degree of overlap between successive areas A11, A12, A13, A14 may be required. In case of for example 10% of one beam as overlap, a processing speed would thereby be reduced by a same factor of 10% in case of a single beam at a time through a same lens. In a situation where there are 5 or more beams projected through a same lens at a time, the same overlap of 10% (similarly referring to one beam example above) would be provided for every 5 or more projected lines, hence reducing a total overlap by a factor of approximately 5 or more to 2% or less, thereby having a significantly lower effect on overall processing speed. Similarly, projecting at least 10 beams may reduce a total overlap by approximately a factor of 10. Thus, effects of tolerances on processing time of a substrate may be reduced by the feature that multiple beams are projected at a time by the same lens. In addition or alternatively, more overlap (hence a larger tolerance band) may be allowed, as the effects thereof on processing are low given that multiple beams are projected at a time by the same lens.

Alternatively or in addition to projecting multiple beams via a same lens at a time, interlacing techniques could be used, which however may require a comparably more stringent matching between the lenses. Thus, the at least two beams projected toward the substrate at a time via the same one of the lenses have a mutual spacing, and the apparatus may be arranged to operate the second actuator so as to move the substrate with respect to the optical column to have a following projection of the beam to be projected in the spacing.

In order to reduce a distance between successive beams in a group in the direction D (thereby e.g. achieving a higher resolution in the direction D), the beams may be arranged diagonally in respect of each other, in respect of the direction D. The spacing may be further reduced by providing a segmented mirror 30 in the optical path, each segment to reflect a respective one of the beams, the segments being arranged so as to reduce a spacing between the beams as reflected by the mirror in respect of a spacing between the beams as incident on the mirror. Such effect may also be achieved by a plurality of optical fibers, each of the beams being incident on a respective one of the fibers, the fibers being arranged so as to reduce along an optical path a spacing between the beams downstream of the optical fibers in respect of a spacing between the beams upstream of the optical fibers.

Further, such effect may be achieved using an integrated optical waveguide circuit having a plurality of inputs, each for receiving a respective one of the beams. The integrated optical waveguide circuit is arranged so as to reduce, along an optical path, a spacing between the beams downstream of the integrated optical waveguide circuit in respect of a spacing between the beams upstream of the integrated optical waveguide circuit.

A system may be provided for controlling the focus of an image projected onto a target portion. The arrangement may be provided to adjust the focus of the image projected by part or all of an optical column in an arrangement as discussed above.

In an embodiment the projection system projects the at least one radiation beam onto a substrate, formed from a layer of material, above the substrate 17 on which a device is to be formed so as to cause local deposition of droplets of the material (e.g. metal) by a laser induced material transfer. Thus, an additive manufacturing process may be realized.

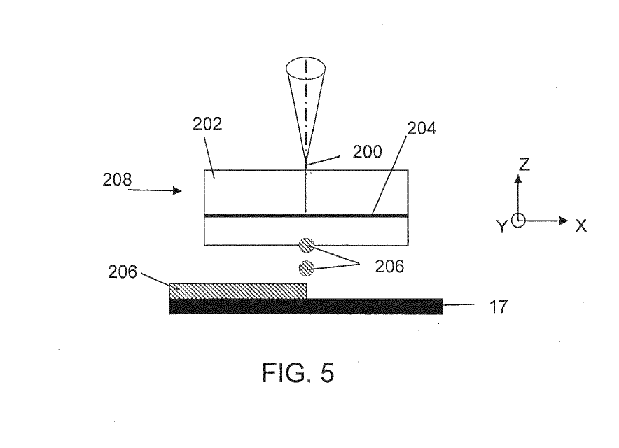

Referring to FIG. 5, the physical mechanism of laser induced material transfer is depicted. In an embodiment, a radiation beam 200 is focused through a substantially transparent material 202 (e.g., glass) at an intensity below the plasma breakdown of the material 202. Surface heat absorption occurs on a substrate formed from a donor material layer 204 (e.g., a metal film) overlying the material 202. The heat absorption causes melting of the donor material 204. Further, the heating causes an induced pressure gradient in a forward direction leading to forward acceleration of a donor material droplet 206 from the donor material layer 204 and thus from the donor structure (e.g., plate) 208. Thus, the donor material droplet 206 is released from the donor material layer 204 and is moved (with or without the aid of gravity) toward and onto the substrate 17 on which a device is to be formed. By pointing the beam 200 on the appropriate position on the donor structure 208, a donor material pattern can be deposited on the substrate 17. In an embodiment, the beam is focused on the donor material layer 204. Thus, references herein to a target portion may be to a target portion on the donor structure 208 and related references to a substrate 17 may be to the donor structure 208. In an embodiment, the donor material structure is configured to move or displace the donor material layer 104.

In an embodiment, one or more short pulses are used to cause the transfer of the donor material. In an embodiment, the pulses may be a few picoseconds or femto-seconds long to obtain quasi one dimensional forward heat and mass transfer of molten material. Such short pulses facilitate little to no lateral heat flow in the material layer 204 and thus little or no thermal load on the donor structure 208. The short pulses enable rapid melting and forward acceleration of the material (e.g., vaporized material, such as metal, would lose its forward directionality leading to a splattering deposition). The short pulses enable heating of the material to just above the heating temperature but below the vaporization temperature. For example, for aluminum, a temperature of about 900 to 1000 degrees Celsius is desirable.

In an embodiment, through the use of a laser pulse, an amount of material (e.g., metal) is transferred from the donor structure 208 to the substrate 17 in the form of 100-1000 nm droplets. In an embodiment, the donor material comprises or consists essentially of a metal. In an embodiment, the metal is aluminum. In an embodiment, the material layer 204 is in the form a film. In an embodiment, the film is attached to another body or layer. As discussed above, the body or layer may be a glass.

In an embodiment, each of the self-emissive contrast devices 4 is a vertical-external-cavity surface-emitting laser (VECSEL) or a vertical-cavity surface-emitting laser (VCSEL). A VECSEL or VCSEL is a relatively small semiconductor laser that emits radiation substantially perpendicularly to the surface of the substrate out of which the emitter is made. Compare this to a laser diode that emits radiation in the plane of the substrate. A consequence of the geometry is that a laser diode is cut out of the wafer and individually mounted in a package. A VECSEL or VCSEL, in contrast, can be made in an individually addressable array at small pitch (e.g. less than 2000 microns, less than 1500 microns, less than 1000 microns, less than 900 microns, less than 800 microns, less than 700 microns, less than 500 microns, less than 300 microns, less than 150 microns, less than 100 microns, between 2-50 microns, between 10-100 microns, between 50-300 microns, between 75-500 microns, between 100-700 microns, about 400 microns, or about 100 microns). In this way the demagnification of the optics can be reduced from e.g. 500× to between 20× to 100× making tolerance issues small. Since the emission area is larger (e.g. 10-15 microns diameter) beam pointing may also be more stable than with a laser diode. Thus, VCSELs and VECSELs have a benefit of array fabrication at a small pitch which can reduce the complexity of illumination optics. VCSELs and VECSELs can offer excellent spectral purity, high power and good beam quality.

In an embodiment, a VECSEL or VCSEL may output about 800 nm radiation e.g., 772 nm, 774 nm or 810 nm radiation. Currently such a VECSEL or VCSEL is available mainly as made of GaAs, and emits radiation with a wavelength selected from the range of about 700-1150 nm. For the additive manufacturing process using laser induced material transfer or particle sintering (as described hereafter), the VECSELs or VCSELs may be operated to deliver their raw output radiation at a wavelength selected from about 700-1150 nm radiation to the donor structure 208. Thus, a high exposure dose can be delivered as needed for the additive manufacturing process. In an embodiment, a VECSEL or VCSEL may output about 400 nm radiation, e.g., 405 nm radiation. Currently such a VECSEL or VCSEL is available mainly as made of GaN.

However, the radiation provided at the target portion may be different than output by the VECSEL or VCSEL. In an embodiment, the VECSEL or VCSEL radiation is converted to about 400 nm, about 248 nm, about 193 nm, about 157 nm, or about 128 nm. In an embodiment, a radiation output of the VECSEL or VCSEL is frequency multiplied to, e.g., about 400 nm, about 248 nm, about 193 nm, about 157 nm, or about 128 nm. In an embodiment, a VECSEL or VCSEL is configured to emit at about 810 nm and the output is frequency doubled to 405 nm. In embodiment, the radiation output is frequency tripled or frequency quadrupled. In an embodiment, the radiation is frequency quadrupled using two stages of frequency doubling. In an embodiment, the frequency multiplication is done by passing the beam through a frequency multiplying (e.g., doubling) crystal. In an embodiment, the frequency multiplication is done using BBO (β-BaB₂O₄), periodically poled lithium niobate (PPLN) and/or KBBF (KBe₂BO₃F₂) non-linear optics. In an embodiment, the frequency quadrupling is done using BBO or PPLN in a first stage and KBBF in a second stage. In an embodiment, the conversion efficiency may be about 1%. In an embodiment, for frequency quadrupling using two stages of frequency doubling, the first stage may have about 20% conversion efficiency and the second stage may have about 5% conversion efficiency. In an embodiment, frequency doubling may be performed intra-cavity. For example, the first stage of frequency doubling may be intra-cavity frequency doubling using BBO or PPLN. The use of frequency multiplication provides the basis for working with various wavelengths, which allows for future customer resolution requirements. The non-linear nature of the frequency conversion may also effectively reduce the background radiation when a laser emitter is maintained above a threshold firing state. The frequency conversion efficiency is less for lower input powers than for higher input powers. Thus, the relative level of background radiation at the desired output wavelength will be lowered by the conversion process.

In an embodiment, a VCSEL and VECSEL may deliver a beam of more than 100 mW. In an embodiment, a VCSEL and VECSEL may deliver a beam with a power selected from the range of 100 mW to 1000 mW. Where a VCSEL and VECSEL output is frequency multiplied, the VCSEL and VECSEL may deliver a beam of 1-20 mW (e.g., a frequency doubled VECSEL of GaAs). Thus, in that case, about ten (10) VCSELs and VECSELs may replace a single laser diode (e.g., a laser diode can emit up to 250 mW from a single emitter). In an embodiment, a dose of up to 20 mJ/cm² (e.g., in a range of 1 to 20 mJ/cm²) may be provided at target portion level by each VCSEL or VECSEL. This dose level may be more than required. Such dose level may afford the use of a non-amplified resist in a resist-based process, which may reduce line edge roughness and/or relax post processing requirements. In an embodiment, the beam may have 4 μW power at target portion level to provide, for example, an exposure dose of up to 20 mJ/cm².

In an embodiment, the beam intensity could be achieved by applying ‘pulsed’ operation on the VECSEL or VCSEL array and the use of a 10× beam reducer which further increases the beam intensity after wavelength doubling and collimation is performed.

A potential improvement could be to mode lock the VECSEL or VCSEL to create short picoseconds pulses. In an embodiment, active mode locking may be used to generate pulses synchronized with the exposure frequency of 100 MHz.

For the additive manufacturing process, about 20 times more power may be required than for the resist-based exposure process. Similarly, the dwell time at each pixel is about at least 1 microsecond for the additive manufacturing process while the resist-based exposure process may have about 5 ns dwell time at each pixel.

The longer dwell time can be mimicked by delivering the dose in burst mode: the plurality (e.g., ten) of VCSELs and VECSELs that deliver dose to a single spot do their job equally spread over at least 1 microsecond. Since part of the optical column may move (e.g., rotate) at about 100 m/s, the spots are spread over a length of at least 100 microns.

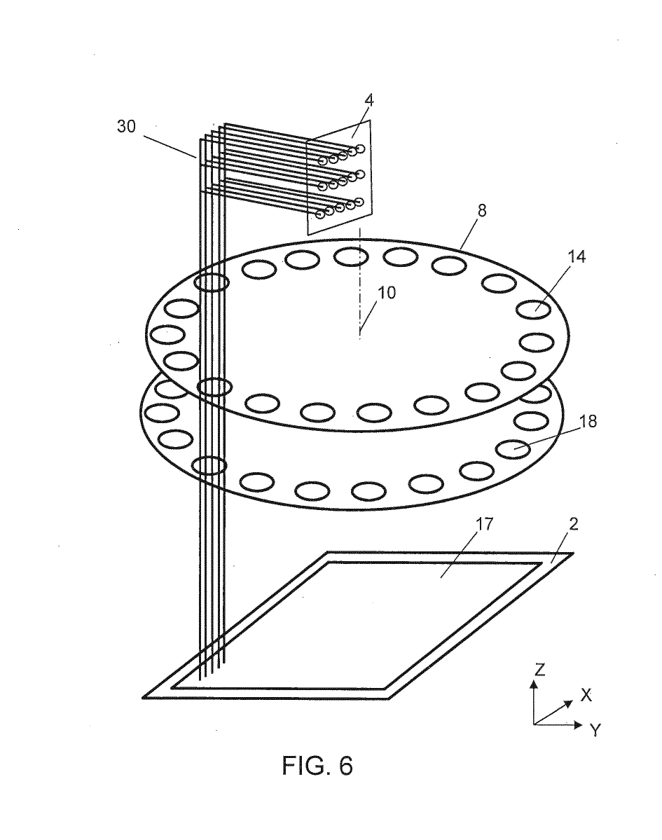

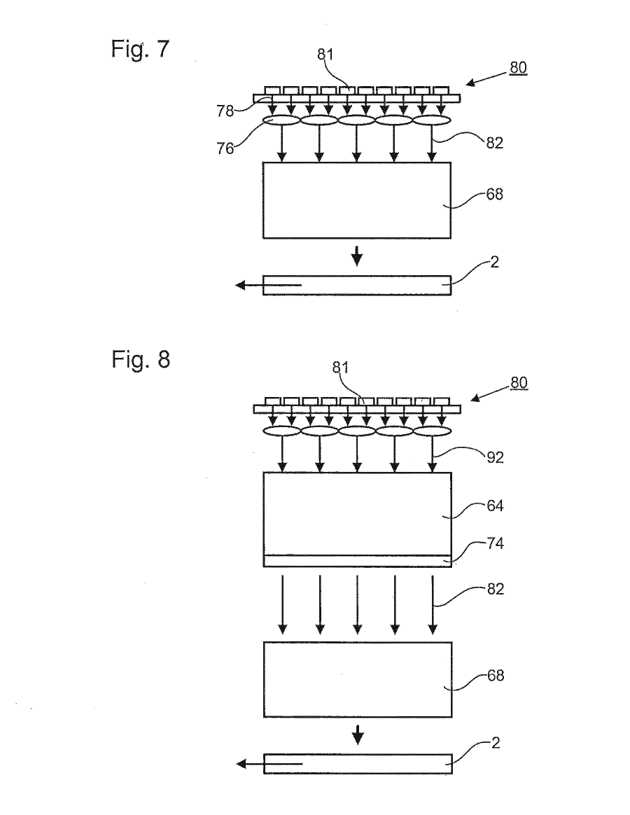

In an embodiment, an array of VECSELs or VCSELs may be provided. The plurality of VECSELs or VCSELs emits a plurality of beams. For example, the array may be provided on a single substrate (e.g., a GaAs wafer). In an embodiment, the array is two-dimensional. In an embodiment, the array may comprise one hundred (100) VECSELs or VCSELs, e.g., in a 10×10 array, thus emitting 100 beams. Other numbers of VECSELs or VCSELs may be used. In an embodiment, there may be an array of VECSELs or VCSELs per optical column for a plurality of optical columns. In an embodiment, the plurality of VECSELs or VCSELs is arranged non-horizontally, e.g., they emit in the X- or Y-direction (see, e.g., FIG. 6). In an embodiment, the plurality of VECSELs or VCSELs is arranged horizontally, i.e., they emit in the Z direction (see, e.g., FIGS. 7 and 8)

VECSELs or VCSELs are top emitters and therefore they can be mounted compactly, for example together on a single substrate. VECSELs or VCSELs can facilitate telecentric projection of beams. In comparison, laser diodes are edge emitters and typically packaged individually. Therefore mounting of laser diodes is typically at a distance of e.g. 1 cm. Therefore, there is significant demagnification towards to target portion to have the laser diode radiation spots close enough to each other, e.g., at a pitch of about 4 microns. Such spacing and/or demagnification of laser diodes may introduce line edge roughness and/or depth of focus issues due to telecentricity errors.

Further, since each laser diode may be replaced by multiple VECSELs or VCSELs (e.g., about 10 VECSELs or VCSELs), redundancy is introduced. For example, if one of 10 VECSELs or VCSELs fails or doesn't operate properly, there are still 9 other VECSELs or VCSELs to provide close to or the same desired radiation power and brightness. Where laser diodes are used, each position on the target portion may be exposed by a single laser diode.

In an embodiment, the plurality of VECSELs or VCSELs may be operated at a fraction of their operating capacity at steady state to allow for redundancy. For example, 10 VECSELs or VCSELs may be operated at around 80% of their capacity during steady state and should one or more of those VECSELs or VCSELs fail or not operate properly, the remaining VECSELs or VCSELs may be operated at a higher percent at steady state (e.g., 88% of their capacity) to provide close to or the same desired radiation power and brightness.

In an embodiment, the self-emissive contrast device comprises more individually addressable elements 102 than needed to allow a “redundant” individually controllable element 102 to be used if another individually controllable element 102 fails to operate or doesn't operate properly. In addition or alternatively, extra individually addressable elements may have an advantage for controlling thermal load on the individually addressable elements as a first set of individually addressable elements may be used for a certain period and then a second set is used for another period while the first set cools.

Similar to the arrangement of FIG. 3, FIG. 6 depicts a highly schematic, perspective view of a rotating frame 8 (provided with lenses 14, 18 at its perimeter) of an optical column employing a plurality of VECSELs or VCSELs 4. A plurality of beams from a plurality of VECSELs or VCSELs 4 are incident onto one of the lenses and projected onto a target portion of, e.g., the substrate 17 held by the substrate table 2 or the donor structure 208. In an embodiment, the beams are arranged in an array comprising a plurality of rows or columns, each row or column having a plurality of beams in a straight line (see, e.g., FIG. 10; while FIG. 6 embodies such a two-dimensional arrangement of beams, the beams are so close together that their two-dimensional arrangement isn't visually apparent in FIG. 6. Rather, see FIG. 10 for the two-dimensional arrangement). Accordingly, the plurality of VECSELs or VCSELs 4 may be similarly arranged in a plurality of rows or columns, each row or column having a plurality of VECSELs or VCSELs in a straight line (e.g., arranged on a single substrate) as shown in FIG. 10. In an embodiment, the plurality of VECSELs or VCSELs 4 may be differently arranged than the beam arrangement and an optical element (for example, mirror 30 described herein) may convert the spatial arrangement of the outputs of the plurality of VECSELs or VCSELs 4 into the spatial arrangement of the beams at the target portion. For example, in FIG. 6 the plurality of VECSELs or VCSELs 4 are depicted as emitting in the X-Y plane and the beams are deflected to travel in the Z-direction. However, the plurality of VECSELs or VCSELs 4 may be arranged in a different orientation than as shown in FIG. 6 (see, e.g., FIGS. 7 and 8) and the beams may be not deflected at all or be deflected at a different angle. Further, while three rows of five VECSELs or VCSELs are shown in FIG. 6, the number of rows and columns may be different (e.g., 10 rows and 10 columns of VECSELs or VCSELs).

The rotatable frame is rotatable about axis 10 by means of an actuator (not shown). As a result of the rotation of the rotatable frame 8, the beams will be incident on successive lenses 14, 18 (field lens 14 and imaging lens 18) and will, incident on each successive lens, be deflected thereby so as to travel along a part of the surface of the target portion, as will be explained in more detail with reference to FIG. 10. In an embodiment, each beam is generated by a respective source, i.e. a self-emissive contrast device, e.g. a VECSEL or VCSEL (not specifically shown in FIG. 6). In the arrangement depicted in FIG. 6, the beams are deflected and brought together by a segmented mirror 30 in order to reduce a distance between the beams, to thereby enable a larger number of beams to be projected through the same lens and to achieve resolution requirements.

As the rotatable frame rotates, the beams are incident on successive lenses and, each time a lens is irradiated by the beams, the places where the beams are incident on a surface of the lens, moves. Since the beams are projected differently (with e.g. a different deflection) depending on the place of incidence of the beams on the lens, the beams (when reaching, e.g., the substrate) will make a scanning movement with each passage of a following lens. This principle is further explained with reference to FIG. 10.

FIG. 7 depicts an embodiment in which a plurality 80 of VECSELs or VCSELs 81 are used as the radiation source. As mentioned above, VECSELs or VCSELs can be configured to emit radiation directly at much smaller pitch than a corresponding plurality of laser diodes. As a result, the subsequent optical demagnification may be reduced. In an embodiment, in order to increase power output per radiation beam, groups of VECSELs or VCSELs may be used together to contribute to the radiation in one output radiation beam 82. For example, the output of two VECSELs or VCSELs may be combined into one output radiation beam 82. An optical system 76 is provided to convert multiple VECSELs or VCSELs emissions 78 from each group to a single output radiation beam 82. Thus, not only does the array of VECSELs or VCSELs provide a plurality of beams, the outputs of a plurality of the VECSELs or VCSELs may be combined to form respective single radiation beams of the plurality of beams. This may introduce further redundancy. For example, since each single beam is associated with a plurality of VECSELs or VCSELs, upon a failure or improper operation of one of the VECSELs or VCSELs, the other VECSELs or VCSELs can provide close to desired radiation power and brightness. Similarly to as discussed above, the output of the VECSELs or VCSELs in this scenario may be operated at a fraction of their operating capacity at steady state to allow for redundancy, i.e., upon failure or improper operation of one or more of the VECSELs or VCSELs, the remaining VECSELs or VCSELs may be operated at a higher capacity to enable the proper power and brightness.

The radiation beams 82 output directly from the VECSELs or VCSELs or from the optical system 76 is then provided to a moving lens system 68 which is configured to project the beams at the desired pitch onto a target moving underneath the lens system 68 on, for example, a substrate table 2. When applied to embodiments of the type depicted in FIGS. 1-6, the moving lens system would comprise the lenses 14 and 18.

In an embodiment, the output radiation beams 82 from the plurality of VECSELs or VCSELs 80 have a wavelength that is 450 nm or less. Thus, in such an embodiment a frequency multiplying device may not be needed in order to generate radiation suitable for lithography. In an embodiment such functionality is achieved using a GaN-based VECSELs or VCSELs. In an embodiment, the VECSELs or VCSELs are configured to output radiation having a wavelength of about 405 nm.

In an embodiment, the output radiation beams 82 from the plurality of VECSELs or VCSELs 80 have a wavelength that is 700-1150 nm. In an embodiment, the VECSELs or VCSELs are GaAs-based VECSELs or VCSELs. In an embodiment, the beams 82 may be converted to a lower wavelength by, e.g., a frequency multiplying device integrated into each VECSEL or VCSEL unit or group of VECSELs or VCSELs units.

FIG. 8 illustrates an embodiment in which the VECSELs or VCSELs 81 are configured in a system to provide a radiation having a wavelength about 405 nm to a target portion. In an example of such an embodiment, the VECSELs or VCSELs 81 are configured to emit radiation 92 having a wavelength of, e.g., about 810 nm. In the embodiment shown, a frequency multiplying device 64 and filter 74 are used to provide a plurality of radiation beams 82 having a wavelength suitable for lithography. In an example embodiment of this type, the VECSELs or VCSELs are configured to emit radiation in the range of 700 nm-1150 nm, for example at 810 nm. In an embodiment, the VECSELs or VCSELs are GaAs-based VECSELs or VCSELs. The radiation beams 82 output from the frequency multiplying device 64 and filter 74 is then provided to a moving lens system 68 which is configured to project the beams at the desired pitch onto a target moving underneath the lens system 68 on, for example, a substrate table 2. When applied to embodiments of the type depicted in FIGS. 1-6, the moving lens system would comprise the lenses 14 and 18.

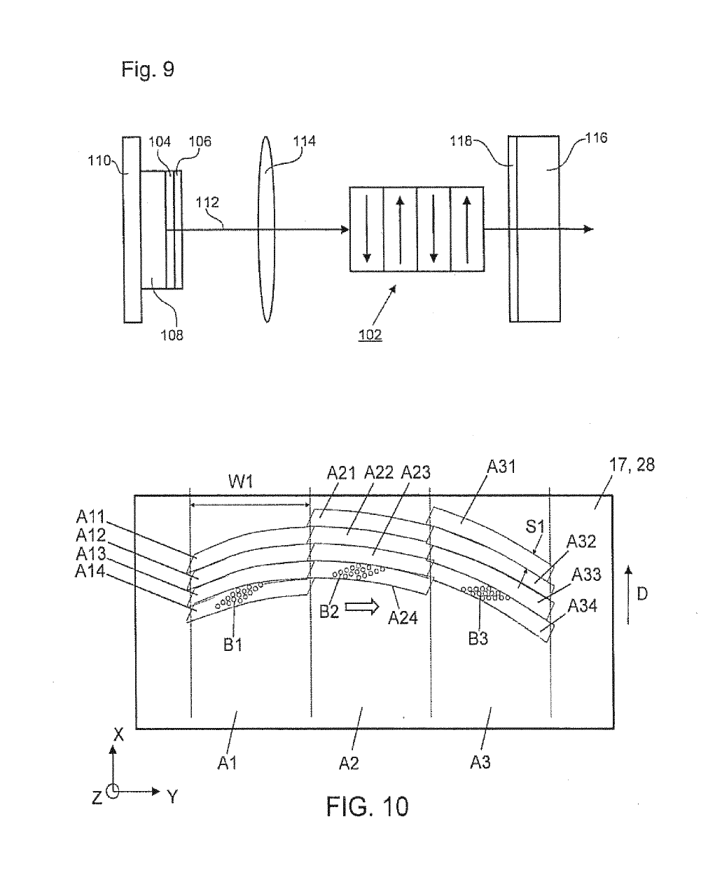

FIG. 9 depicts an example VECSEL unit (produced by Princeton Optronics) comprising an integrated frequency multiplying device 102. In this example the frequency multiplying device comprises a conversion crystal of PPLN (periodically poled lithium niobate). The VECSEL comprises a low doping GaAs substrate 104 with an anti-reflective dielectric coating 106. Region 108 comprises stacks of multiple quantum wells grown on a partially reflective n-type distributed Bragg reflector (DBR). A highly reflective p-type DBR mirror is added to the structure to form an internal optical cavity. A heat-spreader 110, optionally connected to a heat-sink, is provided to remove heat. Radiation 112 is output from the substrate side of the device (bottom emitting). An optical element 114 (e.g., a lens or micro-lens array) focuses the emitted radiation onto the PPLN crystal. In this example, an external cavity is formed by glass mirror 116 and partially reflective dielectric coating 118 to provide the feedback for lasing. A 10 mm long periodically poled PPLN crystal is used as a second harmonic generating crystal. The periodic poling maintains phase matching between the fundamental 980 nm and the second harmonic 490 nm wavelength and provides a long conversion region. To enhance intra-cavity power the dielectric coating 118 is highly reflective at the fundamental wavelength and partially transmissive at the second harmonic wavelength.

In an embodiment, the plurality 80 of VECSELs or VCSELs are provided in an individually addressable array. In an embodiment, the average separation between individual VECSELs or VCSELs is less than or equal to 1000 microns. In an embodiment, the average separation is between 300 and 500 microns.

Similar to FIG. 4, FIG. 10 depicts a highly schematic top view of projections by a part of the frame 8 or optical system 68 of an optical column of FIG. 6, FIG. 7 or FIG. 8 onto a target portion. A first set of beams is denoted by B1, a second set of beams is denoted by B2 and a third set of beams is denoted by B3. Different from the beams in FIG. 4, the sets of beams B1, B2 and B3 comprise a two-dimensional array of beams from a plurality of VECSELs or VCSELs. That is, rather than a single line of beams as shown in FIG. 4, there is a two-dimensional array of beams. While three rows of five beams are shown in FIG. 10, the number of rows and columns may be different (e.g., 10 rows and 10 columns of beams).

Like FIG. 4, each set of beams is projected through a respective lens set 14, 18 of the rotatable frame 8. As the rotatable frame 8 rotates, the beams B1 are projected onto a target portion of, e.g., the substrate 17 in a scanning movement, thereby scanning area A14. Similarly, beams B2 scan area A24 and beams B3 scan area A34. At the same time of the rotation of the rotatable frame 8 by a corresponding actuator, the substrate 17 and substrate table are moved in the direction D (which may be along the X axis as depicted in FIG. 2), thereby being substantially perpendicular to the scanning direction of the beams in the area's A14, A24, A34. As a result of the movement in direction D by a second actuator (e.g. a movement of the substrate table by a corresponding substrate table motor), successive scans of the beams when being projected by successive lenses of the rotatable frame 8, are projected so as to substantially abut each other, resulting in substantially abutting areas A11, A12, A13, A14 (areas A11, A12, A13 being previously scanned and A14 being currently scanned as shown in FIG. 10) for each successive scan of beams B1, areas A21, A22, A23 and A24 (areas A21, A22, A23 being previously scanned and A24 being currently scanned as shown in FIG. 10) for beams B2 and areas A31, A32, A33 and A34 (areas A31, A32, A33 being previously scanned and A34 being currently scanned as shown in FIG. 10) for beams B3. Thereby, the areas A1, A2 and A3 of the substrate surface may be covered with a movement of the substrate in the direction D while rotating the rotatable frame 8. The projecting of multiple beams through a same lens allows processing of a whole substrate in a shorter timeframe (at a same rotating speed of the rotatable frame 8), since for each passing of a lens, a plurality of beams scan the target portion with each lens, thereby allowing increased displacement in the direction D for successive scans. In an embodiment, the beams are arranged such that each beam overlaps or abuts a scanning path of an adjacent beam. In an embodiment, each area A11, A12, etc. has a width W1 of about 12 mm and slit height S1 of about 6 microns (e.g., 6.4 microns).

Alternatively or in addition to projecting multiple beams via a same lens at a time, interlacing techniques could be used, which however may require a comparably more stringent matching between the lenses. Thus, the at least two beams projected onto the target portion at a time via the same one of the lenses have a mutual spacing, and the apparatus may be arranged to operate the second actuator so as to move the substrate with respect to the optical column to have a following projection of the beam to be projected in the spacing.

In order to reduce a distance between successive beams in a group in the direction D (thereby e.g. achieving a higher resolution in the direction D), the beams may be arranged diagonally in respect of each other, in respect of the direction D. As shown in FIG. 10, the beam spots of each row or column of the array of beam spots may be arranged diagonally in respect of each other.

The spacing may be reduced by providing, for example, a segmented mirror 30 as shown in FIG. 6 in the optical path, each segment to reflect a respective one of the beams, the segments being arranged so as to reduce a spacing between the beams as reflected by the mirror in respect of a spacing between the beams as incident on the mirror. Such effect may also be achieved by a plurality of optical fibers, each of the beams being incident on a respective one of the fibers, the fibers being arranged so as to reduce along an optical path a spacing between the beams downstream of the optical fibers in respect of a spacing between the beams upstream of the optical fibers.

Further, such effect may be achieved using an integrated optical waveguide circuit having a plurality of inputs, each for receiving a respective one of the beams. The integrated optical waveguide circuit is arranged so as to reduce along an optical path a spacing between the beams downstream of the integrated optical waveguide circuit in respect of a spacing between the beams upstream of the integrated optical waveguide circuit.

In the embodiments described herein, a controller is provided to control the individually addressable elements (e.g., the VECSELs or VCSELs). For example, in an example where the individually addressable elements are radiation emitting devices, the controller may control when the individually addressable elements are turned ON or OFF and enable high frequency modulation of the individually addressable elements. The controller may control the power of the radiation emitted by one or more of the individually addressable elements. The controller may modulate the intensity of radiation emitted by one or more of the individually addressable elements. The controller may control/adjust intensity uniformity across all or part of an array of individually addressable elements. The controller may adjust the radiation output of the individually addressable elements to correct for imaging errors, e.g., etendue and optical aberrations (e.g., coma, astigmatism, etc.)

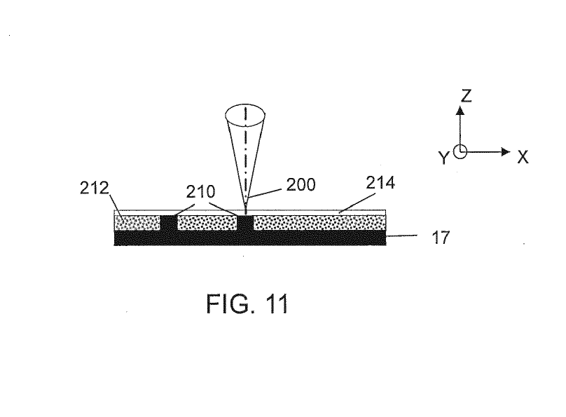

FIG. 11 depicts an embodiment of an additive manufacturing process involving sintering of particles. Referring to FIG. 11, in an embodiment, one or more radiation beams 200 from one or more VECSELs or VCSELs are focused onto a layer comprising particles 212 applied to the substrate 17 (e.g., a glass or silicon substrate). The beam(s) 200 acts a local heat source to induce selective local melting/sintering of the layer (i.e., the particles), which upon cooling form a part 210 of a pattern. In an embodiment, the beam(s) 200 and/or the substrate 17 is relatively moved with respect to the other to form a desired pattern via selective sintering of one or more portions of layer 212. In an embodiment, there may be substantially complete sintering of the one or more portions of the layer. Or, in an embodiment, the one or more portions of the layer (i.e., particles) are partially sintered. In that circumstance, the one or more portions of the layer are attached to the substrate and are not “flushed away” when the non-sintered portion of the layer is removed. In a second step (e.g., baking of the remaining layer in an oven or flood exposure of the remaining layer to a non-patterned beam of radiation), the partially sintered one or more portions of the layer are further sintered, e.g., to be substantially completely sintered.

In an embodiment, the particles are metal, e.g., a conductive metal such as silver. In an embodiment, the particles are selected from the range of 1-900 nanometers in size (e.g., diameter) or from the range of 1-50 nanometers in size. In an embodiment, the particles may be suspended in a solvent, which mixture is applied (e.g., spin coated) on the substrate 2. The solvent is then evaporated to leave a film 212 comprising the particles. Optionally, a film 214 (e.g., PDMS) may applied over the layer 212 to intensify the beam(s) 200 and/or limit efflux of material of layer 212. In an embodiment, the movable frame 8 or the moving lens system 68 is used to apply the beam(s). As discussed above, in an embodiment, the raw output of the one or more VECSELs or VCSELs may be applied to the layer 212. Upon completion of the beam processing, remaining unmelted portion of layer 212 may be removed by, e.g., application of a solvent to leave the beam-processed (metal) pattern. Thus, references herein to a target portion may be to a target portion on the layer 212.

In an embodiment, the movable frame 8 or the moving lens system 68 is not used for the embodiment of FIG. 5 and/or FIG. 11.

In accordance with a device manufacturing method, a device, such as a display, integrated circuit or any other item may be manufactured from the substrate on which the pattern has been projected.

The apparatus may be of a type wherein at least a portion of the substrate may be covered by a liquid having a relatively high refractive index, e.g. water, so as to fill a space between the projection system and the substrate. An immersion liquid may also be applied to other spaces in the apparatus, for example, between a patterning device/modulator and the projection system. Immersion techniques are known in the art for increasing the numerical aperture of projection systems. The term “immersion” as used herein does not mean that a structure, such as a substrate, must be submerged in liquid, but rather only means that liquid is located between the projection system and the substrate during exposure.

Although specific reference may be made in this text to the use of lithographic or exposure apparatus in the manufacture of ICs, it should be understood that the lithographic or exposure apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The term “lens”, where the context allows, may refer to any one of various types of optical components, including refractive, diffractive, reflective, magnetic, electromagnetic and electrostatic optical components or combinations thereof.

An embodiment may take the form of a computer program containing one or more sequences of machine-readable instructions describing a method as disclosed above, or a data storage medium (e.g. semiconductor memory, magnetic or optical disk) having such a computer program stored therein.

Moreover, although certain embodiments and examples have been described, it will be understood by those skilled in the art that the present invention extends beyond the specifically disclosed embodiments to other alternative embodiments and/or uses and obvious modifications and equivalents thereof. In addition, while a number of variations have been shown and described in detail, other modifications, which are within the scope of the invention, will be readily apparent to those of skill in the art based upon this disclosure. For example, it is contemplated that various combination or sub-combinations of the specific features and aspects of the embodiments may be made and still fall within the scope of the invention. Accordingly, it should be understood that various features and aspects of the disclosed embodiments can be combined with or substituted for one another in order to form varying modes of the invention.

So, while various embodiments have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

Thus, the descriptions above are intended to be illustrative, not limiting. Thus, it will be apparent to one skilled in the art that modifications may be made without departing from the scope of the claims set out below.

1. (canceled)

2. An exposure apparatus comprising:
a programmable patterning device having a plurality of radiation sources to provide a plurality of beams; and
a movable frame having optical elements to receive the radiation beams from the plurality of radiation sources and project the beams toward a target portion and a substrate, the optical elements being refractive optical elements, wherein a two-dimensional array of the plurality of the beams is imaged with a single optical element of the plurality of optical elements.

3. The apparatus of claim 2, wherein the substrate is a radiation-sensitive substrate and wherein the optical elements are configured to project the beams onto the target portion of the substrate.

4. The apparatus of claim 2, further comprising a donor structure, in use, located in the optical path from the plurality of radiation sources to the substrate, the donor structure configured to support a donor material layer transferable from the donor structure onto the substrate and onto which the beams impinge.

5. The apparatus of claim 2, wherein the substrate comprises a layer comprising particles and wherein the optical elements are configured to project the beams onto the target portion of the substrate to sinter at least part of the layer.

6. The apparatus of claim 2, wherein the movement comprises rotation and/or the movement causes the beams to displace.

7. (canceled)

8. The apparatus of claim 2, wherein each optical element comprises at least two lenses arranged along a beam path of the two-dimensional array of the plurality of the beams from the plurality of radiation sources to the target portion.

9. The apparatus of claim 2, wherein the array of optical elements is arranged in a two-dimensional array.

10. The apparatus of claim 2, wherein the plurality of radiation sources is arranged in a two-dimensional array.

11. The apparatus of claim 2, wherein the plurality of radiation sources comprises a plurality of VECSELs or VCSELs.

12. The apparatus of claim 2, wherein the plurality of radiation sources comprises a plurality of micro LEDs.

13.-23. (canceled)

24. A device manufacturing method comprising:
modulating a plurality of radiation sources to provide a plurality of beams modulated according to a pattern;
moving a frame having optical elements to receive the radiation beams from the plurality of radiation sources; and
projecting the beams, from the optical elements, toward a target portion and a substrate, the optical elements being refractive optical elements, wherein a two-dimensional array of the plurality of the beams is imaged with a single optical element of the plurality of optical elements.

25. (canceled)

26. The method of claim 24, further comprising a donor structure located in the optical path from the plurality of radiation sources to the substrate, the donor structure supporting a donor material layer transferable from the donor structure onto the substrate and onto which the beams impinge.

27. The method of claim 24, wherein the substrate comprises a layer comprises particles and wherein the optical elements project the beams onto the target portion of the substrate to sinter at least part of the layer.

28. The method of claim 24, wherein the movement comprises rotation and/or the movement causes the beams to displace.

29. The method of claim 24, wherein the array of optical elements is rotated with respect to the beams.

30. The method of claim 24, wherein each optical element comprises at least two lenses arranged along a beam path of the two-dimensional array of the plurality of the beams from the plurality of radiation sources to the target portion.

31. The method of claim 24, wherein the plurality of radiation sources is arranged in a two-dimensional array.

32. The method claim 24, wherein the plurality of radiation sources comprises a plurality of VECSELs or VCSELs.

33. The method of claim 24, wherein the plurality of radiation sources provide the beams of radiation using a VECSEL or VCSEL ,wherein the projecting comprises projecting the beams onto a target portion of a donor layer of a material, the donor layer supported by a donor structure located in the optical path from the VECSEL or VCSEL to the substrate, the beam not being frequency multiplied; and further comprising transferring the material from the donor layer on which the beams impinge from the donor structure onto the substrate.

34. The method of claim 24, wherein the plurality of radiation sources provide the beams of radiation using a VECSEL or VCSEL and wherein the projecting comprises projecting the beams onto thea target portion of a layer comprising particles of a material, the layer on thea substrate and the beam sintering the particles to form a part of a pattern on the substrate.

35.-47. (canceled)
